(19) United States
(12) Patent Application Publication
(10) Pub. No.: US 2013/0083279 A1
(43) Pub. Date: Apr. 4, 2013

(54) LIQUID CRYSTAL DISPLAY DEVICE AND METHOD FOR MANUFACTURING LIQUID CRYSTAL DISPLAY DEVICE

(71) Applicants: Takuo Kinoshita, Tottori (JP); Hiroyuki Ito, Tottori (JP)

(72) Inventors: Takuo Kinoshita, Tottori (JP); Hiroyuki Ito, Tottori (JP)

(73) Assignee: SONY CORPORATION, Tokyo (JP)

(21) Appl. No.: 13/249,563

(22) Filed: Sep. 30, 2011

(51) Int. Cl. G02F 1/1333; H01L 33/00

(52) U.S. Cl. 349/138; 438/30; 257/E33.064

(57) ABSTRACT

A liquid crystal display device includes a pair of substrates of which one substrate is provided with a plurality of scanning lines and a plurality of common wirings, a first insulation film covering the scanning lines, the common wirings, and the one substrate, a plurality of signal lines provided on the first insulation film, a thin film transistor provided near an intersection part of the scanning lines and the signal lines, a lower electrode formed below the first insulation film and connected to the common wirings, a second insulation film formed on surfaces of the thin film transistor, the signal lines, and the first insulation film, and an upper electrode formed on the second insulation film and having a slit, a display region in which the liquid crystal layer is driven by an electric field, and a non-display region that is formed outside the display region.

### CROSS REFERENCE TO RELATED APPLICATIONS

The present disclosure contains subject matter related to that disclosed in Japanese Priority Patent Application JP 2009-075840 filed in the Japan Patent Office on Mar. 26, 2009, the entire contents of which are hereby incorporated by reference.

### BACKGROUND

The present technology relates to a liquid crystal display device of a fringe field switching (referred to below as FFS) mode and a method for manufacturing the liquid crystal display device of the FFS mode. Especially, the present technology relates to a liquid crystal display device of the FFS mode in which short-circuiting between a signal line and a scanning line is suppressed and a method for manufacturing the liquid crystal display device of the FFS mode.

Examples of liquid crystal display devices employing a lateral electric field system include a liquid crystal display device of the FFS mode in which a pair of electrodes which are a pixel electrode and a common electrode is provided only on one substrate. In the liquid crystal display device of the FFS mode, the pixel electrode and the common electrode which are used for applying an electric field to a liquid crystal layer are respectively disposed on different layers with insulation films interposed respectively. The liquid crystal display device of the FFS mode has a wide visual angle, high contrast capability, and higher transmittance and can be driven by low voltage, being able to perform bright display. In addition, the liquid crystal display device of the FFS mode has a large overlapping area of the pixel electrode and the common electrode when viewed from above so as to have such advantage that larger storage capacitance is additionally produced and therefore provision of a separate auxiliary capacitance electrode is not demanded.

However, in manufacturing of a liquid crystal display device, physical vapor deposition such as vacuum vapor deposition and sputtering or organometallic chemical vapor deposition by thermal decomposition has been employed as a deposition method in the related art. Therefore, in such liquid crystal display device of the FFS mode, a step is formed on a position on which a signal line and a common wiring intersect with each other due to lamination of the signal line and the common wiring, and the film thickness of a lateral surface region of the step decreases so as to more likely cause decrease of dielectric pressure. Accordingly, failures such as disconnecting and short-circuiting have sometimes appeared. In the liquid crystal display device of the FFS mode of the related art, a surface of a scanning line is covered by a gate insulation film, a signal line is formed on a surface of the gate insulation film, and a thin film transistor TFT serving as a switching element is formed near an intersection part of the scanning line and the signal line. Therefore, in the manufacturing, after an amorphous silicon (a-Si) layer and an n⁺a-Si layer, for example, are formed on the whole surface of the gate insulation film, a semiconductor layer for forming a TFT is patterned by photolithography. At this time, before the a-Si layer and the n⁺a-Si layer are patterned by the photolithography, there is a cleaning process using pure water. In the cleaning, static electricity is generated between the pure water and the n⁺a-Si layer, and a spark is generated between the n⁺a-Si layer and the scanning line due to the static electricity, so that dielectric breakdown may occur in the gate insulation film which is interposed between the n⁺a-Si layer and a lower electrode.

In formation of a metallic film on a formed fine step in a semiconductor substrate, a ratio between the film thickness in a lateral surface region of the step and the film thickness in a flat part around the step is called step coverage. When the film thickness in the flat part around the step is denoted as A and the film thickness in the lateral surface region of the step is denoted as B, the step coverage is expressed as B/A. As this value becomes larger than 1, the coverage property becomes better. While, as this value becomes smaller than 1, the film thickness of the lateral surface region of the step becomes smaller than the film thickness in the flat part around the step. Accordingly, fine holes or cracks are easily formed in the lateral surface region of the step. Thus, the coverage property is poor.

If a signal line, a source electrode, a drain electrode, and the like are patterned after a source layer is formed on a surface of the gate insulation film in this state, the source layer enters a broken part of the gate insulation film. Accordingly, the signal line and the scanning line short-circuit, sometimes exhibiting a line defect. Such phenomenon occurs because the thickness of the gate insulation film covering lateral surfaces of the scanning line and the signal line is small. The small thickness is caused by the large step formed between the scanning line and the signal line and the poor step coverage of the gate insulation film covering the scanning line and the signal line.

For such problem, Japanese Unexamined Patent Application Publication No. 10-090720 discloses an active matrix substrate in which electrostatic breakdown of an insulation film is prevented. Namely, in the technology disclosed in Japanese Unexamined Patent Application Publication No. 10-090720, when a gate electrode and a source electrode are formed while being overlapped with each other, the source electrode is not formed in a taper part of a gate insulation film in which an insulation property is weaken due to an effect of a step coverage and therefore the source electrode and the source electrode do not overlapped with each other. With such configuration, an electric field can be prevented from being locally applied to a part of a gate insulation film which is on an end part of the gate electrode provided in the taper region in which the insulation property is weakened, and breaking of the gate insulation film caused by static electricity from the outside can be prevented.

### SUMMARY

Thus, short-circuiting between the gate electrode and the source electrode can be prevented in a TFT part with the configuration disclosed in Japanese Unexamined Patent Application Publication No. 10-090720. However, step parts in which the step coverage is poor are inevitably formed by scanning lines and signal lines which are formed on a substrate in matrix, on positions on which the scanning lines and the signal lines intersect with each other. Thus, parts in which the gate insulation film is thin are formed.

Further, such method that a conductive material layer is formed on an intersection part of the scanning line and the signal line can be employed so as to suppress a disconnection defect of the signal line on the intersection part of the scanning line and the signal line or a short-circuiting defect caused by static electricity between the signal line and the scanning line. However, a step is invariably formed on a part in which the step coverage of the gate insulation film is poor, especially, parts of four corners of the intersection of the signal line and the scanning line. Therefore, electrostatic breakdown of the gate insulation film on the scanning lines is not prevented only by providing the conductive material layer between parts, which are intersection parts, of the scanning line and the signal line. Thus, it is difficult to suppress short-circuiting between the scanning line and the signal line.

Therefore, after a great deal of consideration to deal with the above-mentioned problems of the related art, the inventors of the present technology found that short-circuiting between the scanning line and the signal line could be suppressed by forming a conductive material layer, which is formed on the scanning line, to be wide and keeping a spark occurring point away from the signal line, and the inventors completed the present technology. It is desirable to provide a highly reliable liquid crystal display device in which short-circuiting between a scanning line and a signal line is prevented and an occurrence of a line defect is dissolved.

Further, it is desirable to provide a method for manufacturing a liquid crystal display device exhibiting above-mentioned advantageous effects.

According to an embodiment, there is provided a liquid crystal display device including a pair of substrates that sandwich and hold a liquid crystal layer and of which one substrate is provided with a plurality of scanning lines and a plurality of common wirings, which are provided parallel with each other, a first insulation film that covers the scanning lines, the common wirings, and the one substrate, a plurality of signal lines that are provided on the first insulation film in a direction intersecting with the scanning lines and the common wirings, a thin film transistor that is provided near an intersection part of the scanning lines and the signal lines, a lower electrode that is formed below the first insulation film and is connected to the common wirings, a second insulation film that is formed on surfaces of the thin film transistor, the signal lines, and the first insulation film, and an upper electrode that is formed on the second insulation film to overlap with the lower electrode when viewed from above and has a slit, a display region in which the liquid crystal layer is driven by an electric field generated between the lower electrode and the upper electrode, and a non-display region that is formed outside the display region. In the liquid crystal display device, the lower electrodes cover surfaces of the common wirings between adjacent pixels, a conductive material layer that has a same composition as that of the lower electrodes is formed on surfaces of the scanning lines on intersection parts of the scanning lines and the signal lines, and the conductive material layer is extended to a position away from a lateral surface edge part of the signal lines by 10 μm or more.

The liquid crystal display device according to the embodiment includes a pair of substrates that sandwich and hold a liquid crystal layer and of which one substrate is provided with a plurality of scanning lines and a plurality of common wirings, which are provided parallel with each other, a first insulation film that covers the scanning lines, the common wirings, and the one substrate, a plurality of signal lines that are provided on the first insulation film in a direction intersecting with the scanning lines and the common wirings, a thin film transistor that is provided near an intersection part of the scanning lines and the signal lines, a lower electrode that is formed below the first insulation film and is connected to the common wirings, a second insulation film that is formed on surfaces of the thin film transistor, the signal lines, and the first insulation film, and an upper electrode that is formed on the second insulation film to overlap with the lower electrode when viewed from above and has a slit. Accordingly, the liquid crystal display device of the embodiment operates as a liquid crystal display device of the FFS mode. Here, the lower electrode serves as a common electrode and the upper electrode serves as a pixel electrode.

Further, in the liquid crystal display device of the embodiment, the conductive material layer which has the same composition as that of the lower electrodes is formed on the surface of the scanning lines on the intersection part of the scanning lines and the signal lines in a manner to be wider than the width of the signal lines and the width of the scanning lines. The conductive material layer is extended to a position away from the lateral surface edge part of the signal lines by 10 μm or more. The conductive material layer is fundamentally formed to make a step on a position on which the signal lines and the scanning lines intersect with each other gentle and make cutting of the signal lines hard to occur.

With such configuration, even if a spark occurs between the conductive material layer on the scanning lines and the first insulation film due to static electricity generated in cleaning in the manufacturing process and thereby the first insulation film is broken to have damage, the damage is formed on a position away from the signal lines which are formed on the first insulation film, by 10 μm or more. If the conductive material layer formed over the scanning lines is extended to the position away from the lateral surface edge part of the signal lines by 10 μm or more, a sufficient distance to damage formed in the first insulation film can be secured even if variety of the line width of the scanning lines or pattern misalignment in manufacturing is taken into consideration, being able to sufficiently suppress short-circuiting between the signal lines and the scanning lines. Thus, a liquid crystal display device having few line defects can be provided. Here, if the length of the extended part of the conductive material layer from the lateral surface edge part of the signal lines is less than 10 μm, short-circuiting between the scanning lines and the signal lines more easily occurs disadvantageously.

Further, in the liquid crystal display device of the embodiment, the conductive material layer on the scanning lines has the same composition as that of the lower electrodes, and therefore the conductive material layer can be formed simultaneously with the formation of the lower electrodes. Accordingly, a special material and another manufacturing process do not have to be provided. Further, in the liquid crystal display device of the embodiment, the lower electrodes cover the surfaces of the common wirings between the adjacent lower electrodes. It is commonly sufficient that the lower electrode is formed in every region partitioned by the plurality of scanning lines and the plurality of signal lines. If the lower electrode covers also the surface of the common wiring disposed between the adjacent lower electrodes, no step is formed on the first insulation film on both sides of the signal lines, on a part on which the signal lines and the common wirings intersect with each other. Therefore, dielectric breakdown of the first insulation film caused by static electricity generated in the cleaning can be suppressed on this position as well.

In the liquid crystal display device according to the embodiment, it is preferable that a dummy pixel be formed in the non-display region, and the conductive material layer that is formed on the intersection parts of the signal lines and the scanning lines be formed in the dummy pixel.

The dummy pixel region is formed in a region adjacent to the display region, that is, the dummy pixel region is a region which does not contribute to actual display. However, thanks to the provision of the dummy pixel, the film thickness of each layer in the display region and the film thickness of each layer in the dummy pixel can be set to be same as each other. Therefore, adverse affect caused by adjacency with the non-display region is less imparted to display image quality of pixels of a circumferential part of the display region. Further, the dummy pixel is formed in the periphery of the display region, so that the dummy pixel can absorb stress from outside such as static electricity and therefore, can suppress an occurrence of defects in pixels within the display region. According to the liquid crystal display device of the embodiment, short-circuiting between the signal lines and the common wirings can be suppressed in the dummy pixel as well, so that a highly reliable liquid crystal display device in which an occurrence of a defect of display pixels in the display region is suppressed by appropriate performance of the dummy pixel can be provided.

According to another embodiment, there is a method for manufacturing a liquid crystal display device includes (1) covering a whole surface of a transparent substrate by a conductive layer and etching the conductive layer so as to pattern a plurality of scanning lines having a gate electrode part and a plurality of common wirings in parallel with each other, (2) covering a whole surface of a substrate obtained in the process (1) by a transparent conductive layer and then etching the transparent conductive layer so as to form lower electrodes that are electrically connected with the common wirings on positions corresponding to respective pixels and form a transparent conductive material layer on surfaces of the common wirings between the lower electrodes, and patterning the transparent conductive material layer on a position on which the scanning lines and signal lines, the signal lines being to be formed in a following process, intersect with each other, so as to be set to be wider than a width of the signal lines and a width of the scanning lines and be extended to a position away from a lateral surface edge part of the signal lines by 10 μm or more, (3) covering a whole surface of a substrate obtained in the process (2) by a first insulation film, (4) covering a whole surface of the first insulation film by a semiconductor layer and etching the semiconductor layer so as to pattern the semiconductor layer on a position corresponding to a gate electrode part, (5) covering a whole surface of a substrate obtained in the process (4) by a conductive layer and etching the conductive layer so as to provide the signal lines in a direction intersecting with the scanning lines and the common wirings and pattern a drain electrode and a source electrode that is electrically connected to the signal lines in each of the pixels, (6) covering a whole surface of a substrate obtained in the process (5) by a second insulation film, (7) forming a contact hole in the second insulation film which is positioned on the drain electrode of each of the pixels, (8) covering a whole surface of a substrate obtained in the process (7) by a transparent conductive layer and etching the transparent conductive layer so as to pattern an upper electrode having a plurality of slits in each of the pixels and electrically conduct the upper electrode and the drain electrode, and (9) disposing a substrate obtained in the process (8) and a color filter substrate opposed to each other and filling a space between the substrates with liquid crystal.

According to the method for manufacturing a liquid crystal display device of the other embodiment, a liquid crystal display device which exhibits the above-described advantageous effects can be manufactured.

Additional features and advantages are described herein, and will be apparent from the following Detailed Description and the figures.

### BRIEF DESCRIPTION OF THE FIGURES

FIG. 1 is a plan view of a liquid crystal display device of a FFS mode according to an embodiment;

FIG. 2 is a plan view schematically showing a part, which corresponds to two pixels, of an array substrate of the liquid crystal display device of the FFS mode according to the embodiment;

FIG. 3 is a schematic sectional view taken along a line of FIG. 2;

FIGS. 4A to 4F are sectional views of a part corresponding to the III-III line of FIG. 2 and sequentially showing a manufacturing process of the array substrate of the embodiment corresponding to two pixels;

FIGS. 5A to 5C are sectional views sequentially showing the manufacturing process, which follows the process of FIGS. 4A to 4F, of the array substrate of the embodiment corresponding to two pixels;

FIG. 6A is an enlarged plan view transparently showing a VIA part of FIG. 2 to a signal line, and FIG. 6B is a sectional view taken along a VIB-VIB line of FIG. 6A;

FIG. 7A is an enlarged plan view corresponding to FIG. 6A and showing a state that damage is formed in an insulation film of the embodiment, and FIG. 7B is a sectional view taken along a VIIB-VIIB line of FIG. 7A;

FIG. 8A is a sectional view of a related art example corresponding to FIG. 6B, and FIG. 8B is a sectional view showing a spark state;

FIG. 9A is a plan view showing a short-circuiting state of the related art example and corresponding to FIG. 6A, and FIG. 9B is a sectional view taken along a IXB-IXB line of FIG. 9A; and

FIG. 10 is a graph showing a measurement result of generation distance of a spark and the number of pieces.

### DETAILED DESCRIPTION

Embodiments will be described with reference to the accompanying drawings. Here, it should be noted that the embodiments described below exemplify a liquid crystal display device of a FFS mode as a liquid crystal display device for embodying a technological thought of the present technology, therefore, the scope of the present technology is not limited to this liquid crystal display device of the FFS mode, and the present technology is equally applicable to liquid crystal display devices of other embodiments within the scope of the present technology. In respective drawings used for the description in this specification, scales of respective layers and respective members shown are adequately changed in the extent to which the layers and members can be recognized in the drawings, and thus the layers and the members are not necessarily shown in proportion to actual dimensions.

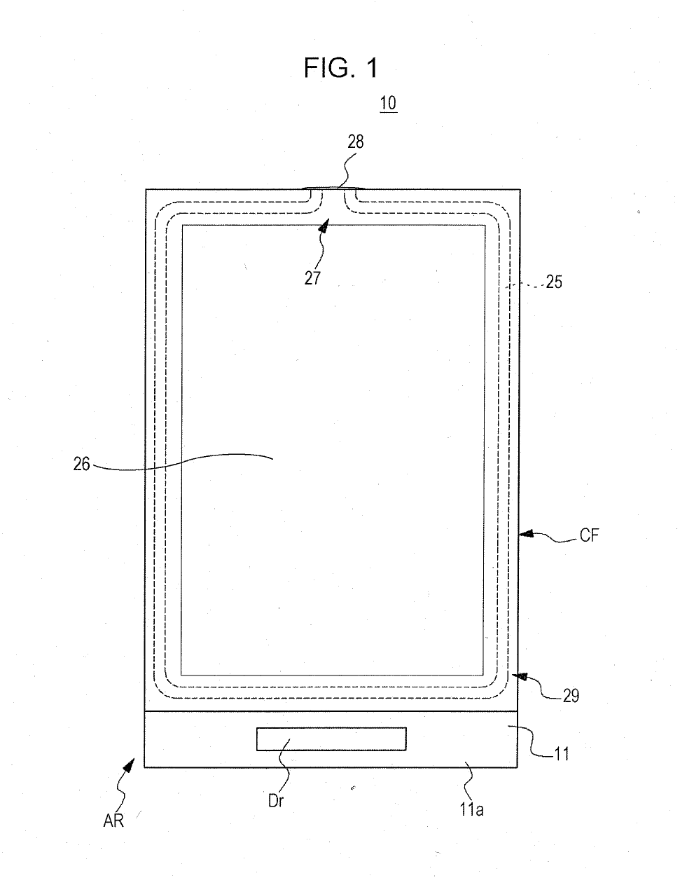

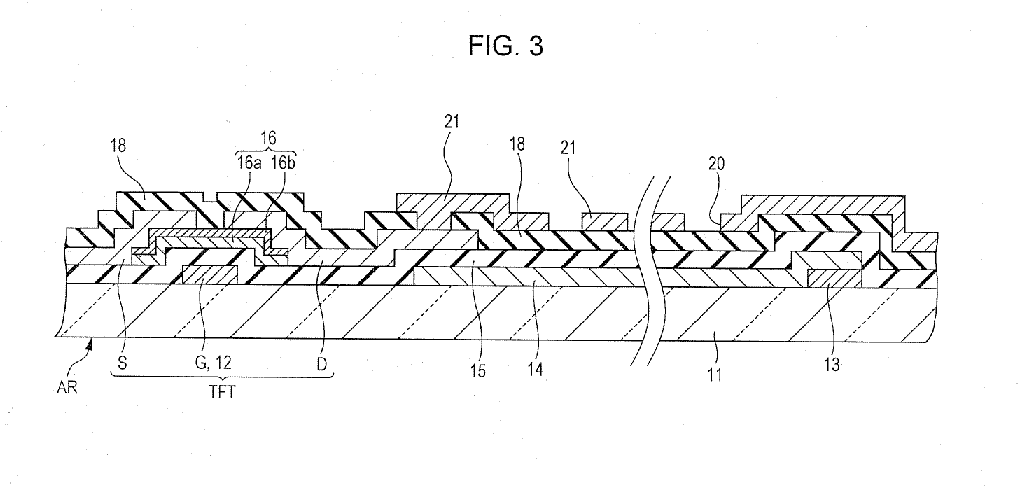

A liquid crystal display device 10 of a FFS mode according to an embodiment is described with reference to FIGS. 1 to 7B. The liquid crystal display device 10 according to the embodiment includes an array substrate AR, a color filter substrate CF, and a sealing member 25 which bonds the substrates AR and CF to each other as shown in FIG. 1. In the liquid crystal display device 10, liquid crystal (not shown) is injected into a region surrounded by the array substrate AR, the color filter substrate CF, and the sealing member 25 from a liquid crystal injection port 27 and the liquid crystal injection port 27 is sealed by a sealing member 28. That is, the liquid crystal display device 10 is so-called a liquid crystal display device of a chip on glass (COG) system. In the liquid crystal display device 10, a region surrounded by the sealing member 25 constitutes a display region 26, and a region which is provided on the periphery of the display region 26 and in which an image is not recognized constitutes a non-display region 29 of the liquid crystal display device 10.

The array substrate AR is formed such that various kinds of wirings for driving the liquid crystal and the like are formed on a surface of a first transparent substrate 11 which is made of glass or the like and has a rectangular shape. The array substrate AR has the longer length in the longitudinal direction than the color filter substrate CF so as to have an extending part 11a which extends outward when the substrates AR and CF are bonded to each other. On the extending part 11a, a driver Dr which is composed of an IC chip, an LSI, or the like which outputs a driving signal is provided.

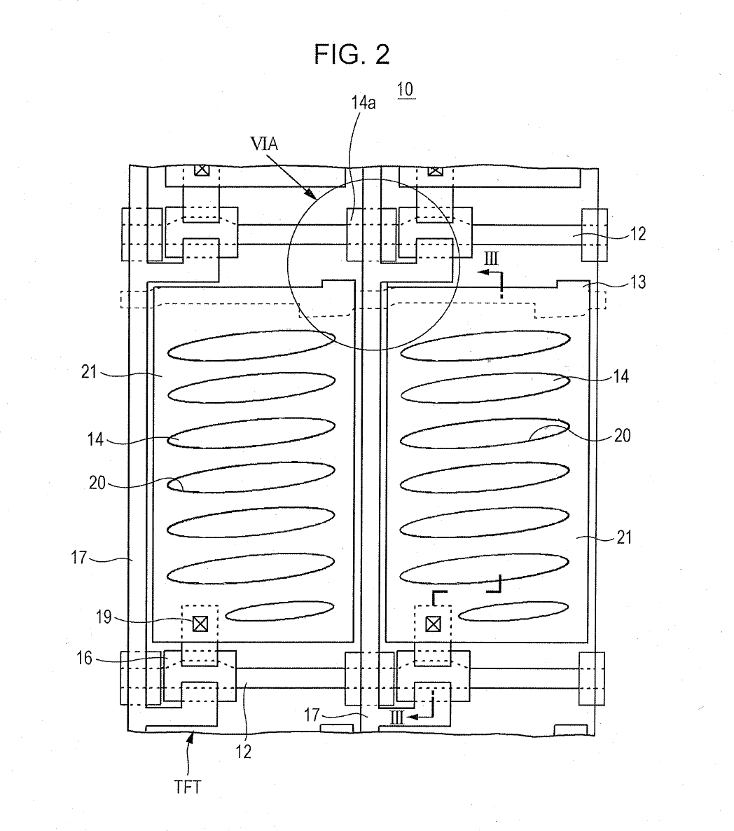

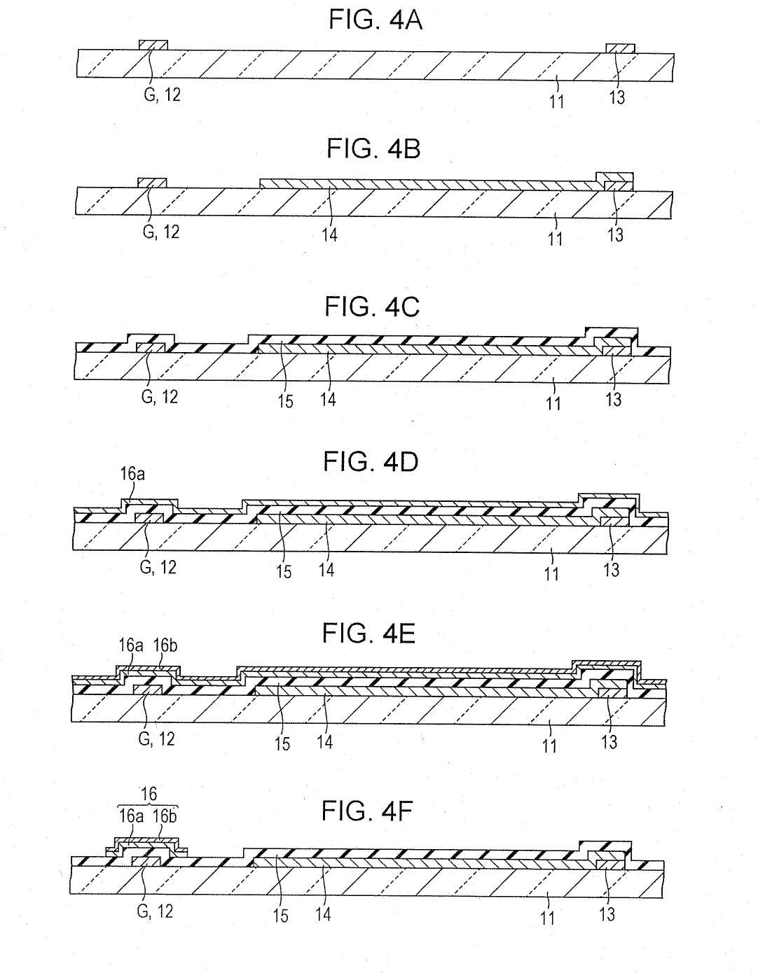

On the array substrate AR of the liquid crystal display device 10 of the FFS mode of the embodiment, a plurality of scanning lines 12 and a plurality of common wirings 13 are formed on the whole surface of the transparent substrate 11 by photolithography, etching, or the like in a manner to be parallel with each other (refer to FIGS. 2 and 4A). Here, in the liquid crystal display device 10 of the embodiment, the common wiring 13 is disposed in a manner to be shifted to a side of one scanning line 12 so as to improve an aperture ratio and display image quality.

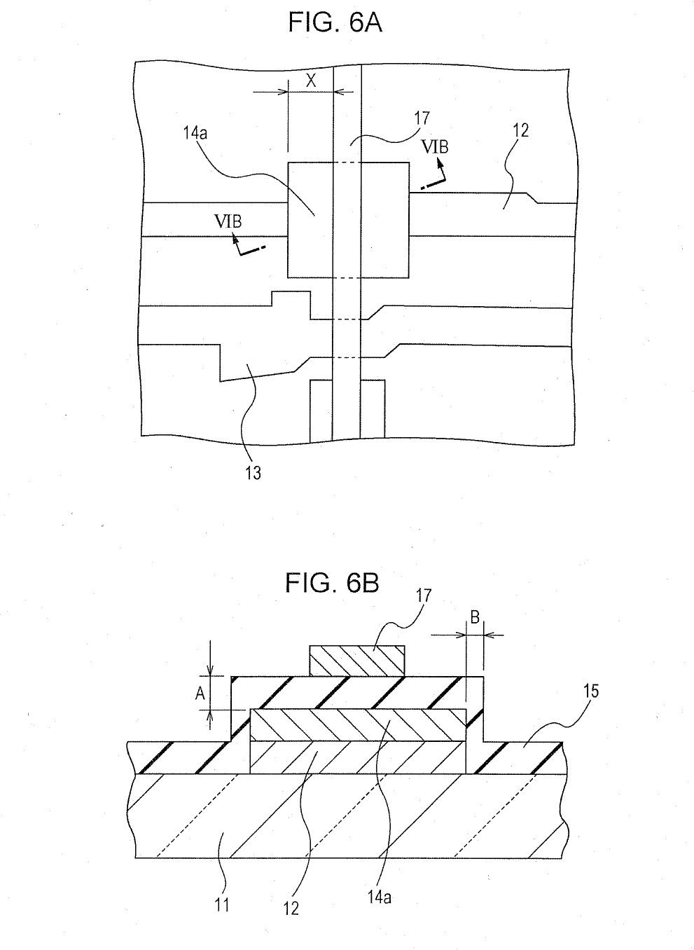

Subsequently, the whole surface of the transparent substrate 11 on which the scanning lines 12 and the common wirings 13 are formed is covered by a transparent conductive layer made of indium tin oxide (ITO), indium zinc oxide (IZO), or the like and a lower electrode 14 is formed by photolithography or the like in the same manner (refer to FIG. 4B). At this time, a conductive material layer 14a is formed in a manner to be extended from a pixel region so as to cover an intersection part of the scanning line 12 and the signal line 17 as shown in FIGS. 2, 6A, and 6B.

After the lower electrode 14 and the conductive material layer 14a are formed in such way, a first insulation film (gate insulation film) 15 which is a silicon nitride layer, for example, is formed to cover the whole surface of the substrate (refer to FIG. 4C).

Subsequently, after the whole surface of the first insulation film 15 is covered by an a-Si layer 16a and n⁺a-Si layer 16b in sequence, a semiconductor layer 16 composed of the a-Si layer 16a and the n⁺a-Si layer 16b is formed in a TFT forming region also by photolithography or the like (refer to FIGS. 4D to 4F). A region, which corresponds to a position on which the semiconductor layer 16 is formed, of the scanning line 12 constitutes a gate electrode G of a TFT.

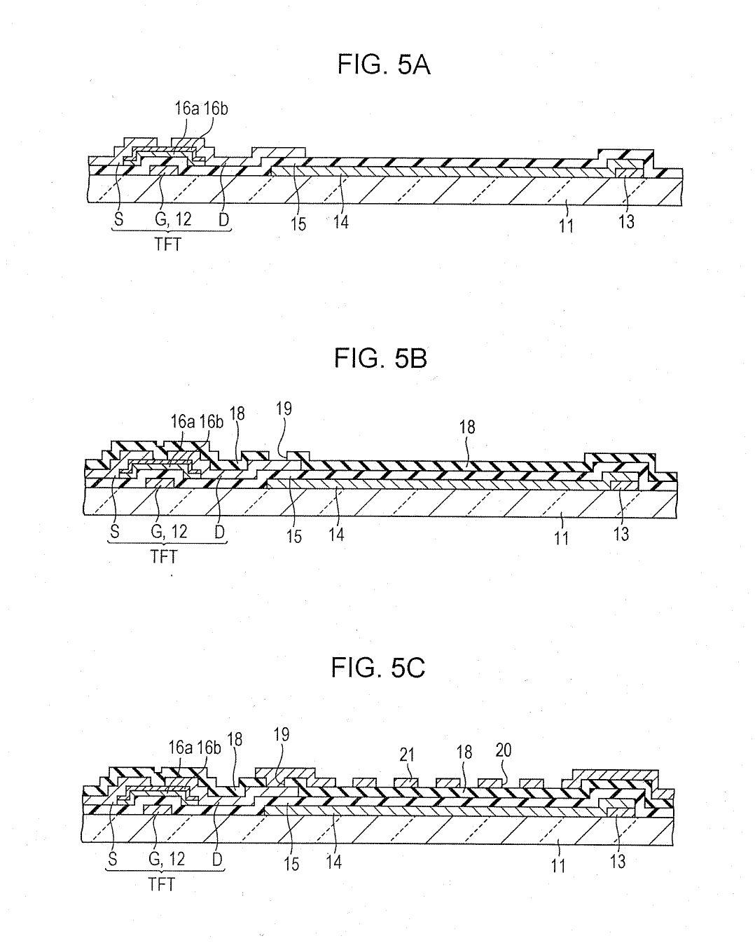

Then, the whole surface of the transparent substrate 11 on which the semiconductor layer 16 is formed is covered by a conductive layer, and the signal line 17 and a drain electrode D are formed also by photolithography or the like (refer to FIG. 5A). Both of a source electrode S part and a drain electrode D part of the signal line 17 are partially overlapped with the surface of the semiconductor layer 16.

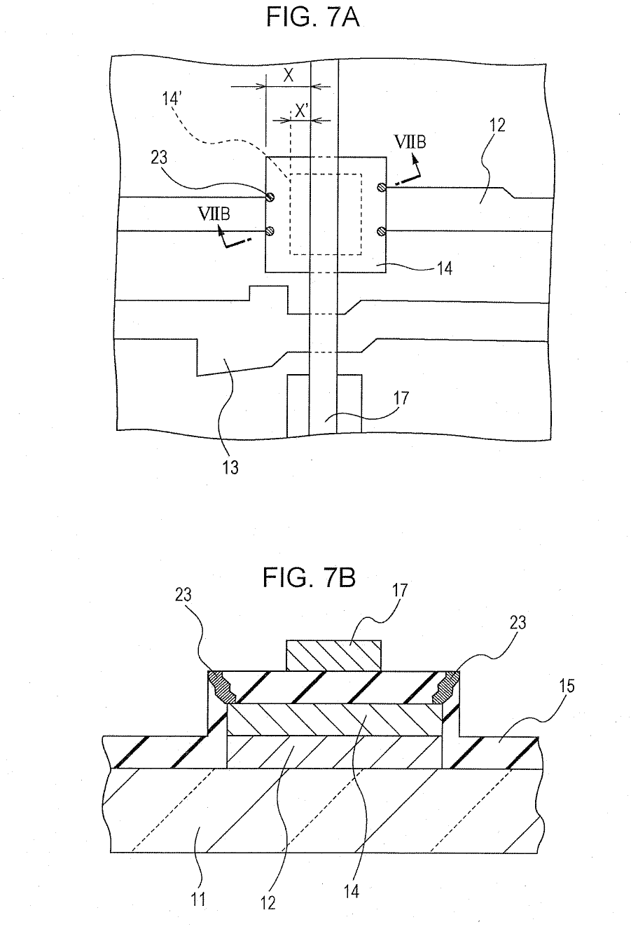

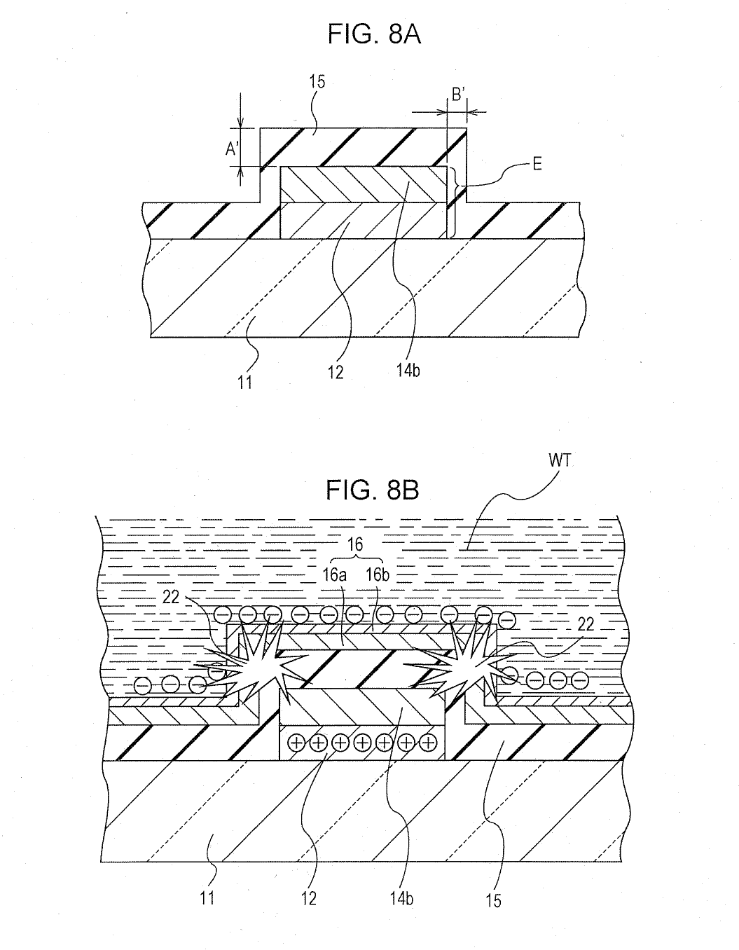

Here, a case of the embodiment and a case of a related art example are compared and explained with reference to FIGS. 7A to 9B. A process shown in FIG. 4F includes a process of cleaning the substrate by pure water WT after the semiconductor layer 16 is formed. In the related art example, the conductive material layer 14b which is made of the same material as that of the lower electrode has an edge part E and the first insulation film 15 is formed to cover the conductive material layer 14b as shown in FIGS. 7A and 8A, so that the thickness B′ of the insulation film formed on the edge part E is smaller than the thickness A′ of a flat part of the first insulation film 15. Thus, step coverage (B′/A′) of the first insulation film 15 formed on the scanning lines 12 is poor.

It is preferable that a measuring part of the film thickness A of the flat part of the first insulation film which is used for calculation of a value of the step coverage (B/A) in the embodiment be the flat part center of a step uppermost part or the flat part of a step periphery, and it is preferable that a measuring part of the film thickness B of the lateral surface region be the thinnest part of the step part. Accordingly, a value of the step coverage (B/A) can be accurately calculated.

It is favorable that the value of the step coverage (B/A) which is a ratio of the film thickness A of the flat part of the first insulation film and the film thickness B of the lateral surface region in the embodiment is set to be 1 or more. Accordingly, the film thickness B of the lateral surface region is sufficiently thick compared to the film thickness A of the flat part, substances for forming a film sufficiently remain also on the lateral surface region of the step part, and therefore, a metal film or an insulation film can be stably formed without generation of fine holes or an occurrence of cracks. Accordingly, sufficient dielectric pressure can be imparted to the first insulation film, so that the dielectric strength of the first insulation film can be increased and short-circuiting between the signal line and the common wiring can be further suppressed, being able to provide a liquid crystal display device in which an occurrence of a line defect is reduced. If the value of the step coverage (B/A) is less than 1, the film thickness B of the lateral surface region is small compared to the film thickness A of the flat part, substances for forming a film do not sufficiently remain on the lateral surface region of the step part as well, and fine holes or cracks are generated. Therefore, short-circuiting between the lower electrode and the signal line more frequently occurs disadvantageously.

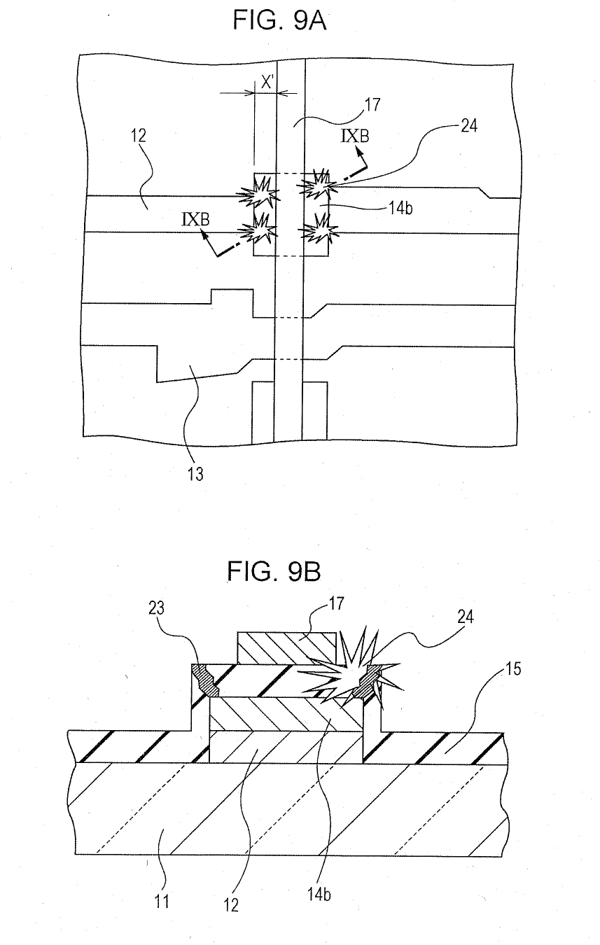

At this time, the semiconductor layer 16 is formed also on the scanning lines 12 and is cleaned as shown in FIG. 8B. Therefore, during the cleaning by the pure water WT, static electricity generated by friction between the pure water and the n⁺a-Si layer 16b causes a spark 22 with the conductive material layer 14b which is formed on the scanning lines 12. Accordingly, the first insulation film 15 which is thinly formed on the conductive material layer 14b is broken and thus damage 23 is formed (refer to FIG. 9B). Then, if the process shown in FIG. 5A is performed while leaving the damage 23 in the first insulation film 15, the source layer enters the damage 23, which is formed when the first insulation film 15 is broken, in source layer formation. Accordingly, even though the signal line 17 is formed by etching processing of the source layer, short-circuiting 24 between the signal line 17 and the scanning line 12 may occur, as shown in FIGS. 9A and 9B.

In the embodiment, the conductive material layer 14a which is made of the same material as that of the lower electrode 14 is formed on an intersection part of the scanning line 12 and the signal line 17 in a manner to have the large width such that the width X from the edge part of the lateral surface of the signal line 17 satisfies the relationship of the width X≧10 μm, as shown in FIGS. 6A to 7B. In the related art example, the conductive material layer 14b stays away from the signal line 17 merely by a small width which is expressed as the width X′<10 μm, as shown FIGS. 7A and 9A. Therefore, the spark 22 caused by static electricity occurs on a position near the signal line 17 and the damage 23 formed in the first insulation film 15 due to the spark 22 is also formed near the signal line 17, whereby the short-circuiting 24 between the scanning line 12 and the signal line 17 may occur (refer to FIG. 9B).

However, in the embodiment, the damage 23 of the first insulation film 15 stays away from the signal line 17 by the width X≧10 μm as shown in FIGS. 7A and 7B. Accordingly, even if the spark 22 occurs, the damage 23 is formed on a position distant from the signal line 17, so that an occurrence of the short-circuiting 24 between the signal line 17 and the scanning line 12 caused by the damage 23 is suppressed. That is, in the embodiment, even if the damage 23 is formed in the first insulation film 15 due to static electricity, the formation of the damage 23 does not affect and the short-circuiting between the signal line 17 and the scanning line 12 can be suppressed.

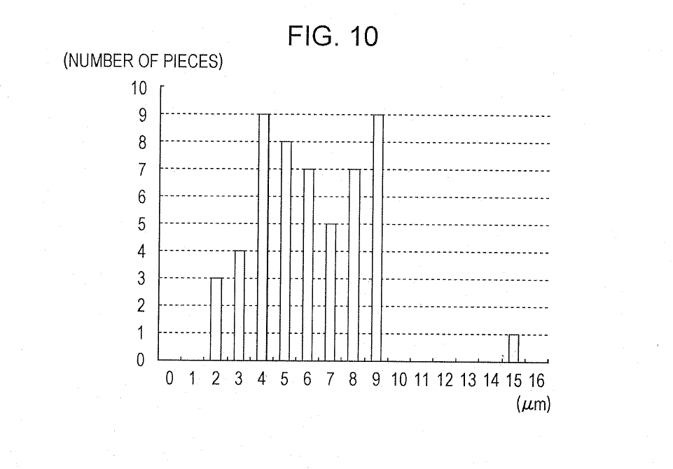

Here, the width X of the conductive material layer 14a has to satisfy the relationship of X≧10 μm. The reason is described with reference to FIG. 10. FIG. 10 shows a distance from an edge part of the transparent conductive material and the number of pieces among 53 pieces of samples when the surface of a gate insulation film was scanned by a needlelike probe and a spark occurred. In the 53 pieces of samples, a layer made of a transparent conductive material was formed on a surface of a scanning line and a gate insulation film made of silicon nitride was formed on a surface of the layer so as to have the thickness of 0.4 μm. Here, a voltage applied between the needlelike probe and the scanning line was direct-current voltage of 1 kV and the measurement was performed by scanning the surface of the gate insulation film by the needlelike probe from a distant position toward the layer made of the transparent conductive material. In the experiment result shown in FIG. 10, a horizontal axis represents distance in increments of 1 μm, and a vertical axis represents the number of pieces, when standard deviation was calculated based on the measurement result. From the result shown in FIG. 10, it is understood that a distance from a lateral surface edge part of the conductive material layer 14a formed on the surface of the scanning line 12 to a lateral surface edge part of the signal line is preferably 10 μm or more.

Subsequently, in order to complete the liquid crystal display device 10 of the embodiment, after the whole surface of this substrate is covered by a second insulation film 18 which is a silicon nitride layer, a contact hole 19 is formed on the second insulation film 18 on a position corresponding to the drain electrode D so as to expose a part of the drain electrode D (refer to FIG. 5B). Then, a transparent conductive layer made of ITO or the like is formed to cover the whole surface, and an upper electrode 21 including a plurality of slits 20, which are parallel to each other, is formed on a part, which is surrounded by the scanning line 12 and the signal line 17, of the second insulation film 18 also by photolithography or the like, as shown in FIG. 1 (refer to FIG. 5C). By forming the slits, a fringe field effect can be generated. The upper electrode 21 is electrically connected with the drain electrode D via the contact hole 19, so that the upper electrode 21 functions as a pixel electrode.

Then, by forming a predetermined alignment film (not shown) is formed to cover the whole surface, the array substrate AR is completed. The array substrate AR manufactured as described above and the color filter substrate CF which is separately manufactured are faced to each other, then the peripheries of the substrates AR and CF are bonded to each other with the sealing member 25, and a space formed between the substrates AR and CF is filled with liquid crystal. Accordingly, the liquid crystal display device 10 of the FFS mode according to the embodiment is obtained. The detailed description of the color filter substrate CF is omitted, but the color filter substrate CF has the substantially same configuration as that of a liquid crystal display device of a twisted nematic (TN) system of the related art except that a color filter layer, an overcoat layer, and an alignment film are layered on a surface of the transparent substrate made of glass or the like and no common electrode is provided.

According to the liquid crystal display device of the FFS mode of the embodiment which is manufactured as described above, even though damage is formed in the first insulation film due to static electricity in cleaning in the manufacturing process, the position of the damage can be kept sufficiently away from the signal line and therefore, short-circuiting between the scanning line and the signal line can be suppressed. Thus, a highly reliable liquid crystal display device can be provided.

Further, it is favorable that a dummy pixel is formed in the non-display region 29 of the liquid crystal display device of the embodiment and a transparent conductive material layer which is formed on the surface of the scanning line is formed in the dummy pixel. The dummy pixel is preferentially broken by static electricity and thus also has a function to prevent the static electricity from adversely affecting the pixel within the display region. Therefore, the dummy pixel can prevent the static electricity from adversely affecting the pixel in the display region as long as the dummy pixel functions properly, being able to provide a further highly reliable liquid crystal display device.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A liquid crystal display device comprising:
a pair of substrates that sandwich and hold a liquid crystal layer and of which one substrate is provided with,
a plurality of scanning lines and a plurality of common wirings, the scanning lines and the common wirings being provided in parallel with each other,
a first insulation film that covers the scanning lines, the common wirings, and the one substrate,
a plurality of signal lines that are provided on the first insulation film in a direction intersecting with the scanning lines and the common wirings,
a thin film transistor that is provided near an intersection part of the scanning lines and the signal lines,
a lower electrode that is formed below the first insulation film and is connected to the common wirings,
a second insulation film that is formed on surfaces of the thin film transistor, the signal lines, and the first insulation film, and
an upper electrode that is formed on the second insulation film to overlap with the lower electrode when viewed from above and that has a slit;
a display region in which the liquid crystal layer is driven by an electric field generated between the lower electrode and the upper electrode; and
a non-display region that is formed outside the display region; wherein
the lower electrodes cover surfaces of the common wirings between adjacent pixels,
a conductive material layer that has a same composition as that of the lower electrodes is formed on surfaces of the scanning lines on intersection parts of the scanning lines and the signal lines, and
the conductive material layer is extended to a position away from a lateral surface edge part of the signal lines by 10 μm or more.

2. The liquid crystal display device according to claim 1, wherein a dummy pixel is formed in the non-display region, and the conductive material layer that is formed on the intersection parts of the signal lines and the scanning lines is formed in the dummy pixel.

3. A method for manufacturing a liquid crystal display device, the method comprising:
(1) covering a whole surface of a transparent substrate by a conductive layer and etching the conductive layer so as to pattern a plurality of scanning lines having a gate electrode part and a plurality of common wirings in parallel with each other;
(2) covering a whole surface of a substrate obtained in the process (1) by a transparent conductive layer and then etching the transparent conductive layer so as to form lower electrodes that are electrically connected with the common wirings, on positions corresponding to respective pixels and form a transparent conductive material layer on surfaces of the common wirings between the lower electrodes, and patterning the transparent conductive material layer on a position on which the scanning lines and signal lines, the signal lines being to be formed in a following process, intersect with each other, so as to be set to be wider than a width of the signal lines and a width of the scanning lines and be extended to a position away from a lateral surface edge part of the signal lines by 10 μm or more;
(3) covering a whole surface of a substrate obtained in the process (2) by a first insulation film;
(4) covering a whole surface of the first insulation film by a semiconductor layer and etching the semiconductor layer so as to pattern the semiconductor layer on a position corresponding to a gate electrode part;
(5) covering a whole surface of a substrate obtained in the process (4) by a conductive layer and etching the conductive layer so as to provide the signal lines in a direction intersecting with the scanning lines and the common wirings and pattern a drain electrode and a source electrode that is electrically connected to the signal lines in each of the pixels;
(6) covering a whole surface of a substrate obtained in the process (5) by a second insulation film;
(7) forming a contact hole on the second insulation film which is positioned on the drain electrode of each of the pixels;
(8) covering a whole surface of a substrate obtained in the process (7) by a transparent conductive layer and etching the transparent conductive layer so as to pattern an upper electrode having a plurality of slits in each of the pixels and electrically conduct the upper electrode and the drain electrode; and
(9) disposing a substrate obtained in the process (8) and a color filter substrate opposed to each other and filling a space between the substrates with liquid crystal.
